(19) United States
(12) Patent Application Publication
(10) Pub. No.: US 2011/0163337 A1
(43) Pub. Date: Jul. 7, 2011

(54) ARCHITECTURE FOR ORGANIC ELECTRONIC DEVICES

(75) Inventors: Joseph John Shiang, Niskayuna, NY (US); Anil Raj Duggal, Niskayuna, NY (US); Jeffrey Michael Youmans, Saratoga Springs, NY (US)

(73) Assignee: GENERAL ELECTRIC COMPANY, Schenectady, NY (US)

(21) Appl. No.: 12/683,355

(22) Filed: Jan. 6, 2010

(51) Int. Cl. H01L 33/00; H01L 21/30

(52) U.S. Cl. 257/98; 438/29; 257/E33.061; 257/E21.211

(57) ABSTRACT

Provided are organic device packages configured to limit current flow through shorted sub-elements in the organic device. In some embodiments, the organic device package may include multiple elements, each having multiple sub-elements connected in parallel. Each element may have a first electrode patterned into thin electrode strips connected in parallel, and each of the electrode strips may be an electrode of one of the multiple sub-elements. The electrode strips may have a resistance which may be higher than the overall resistance of other sub-elements in the element, such that a current flowing to the element may be substantially limited from flowing through a shorted sub-element in the element. Each element may also be connected in series to another element in the organic device package, and one or more series-connected elements may also be connected in parallel within the package.

### BACKGROUND

The subject matter disclosed herein relates to lighting devices, and more particularly to optoelectronic devices.

Currently, optoelectronic devices, such as, but not limited to, organic light emitting diodes (OLEDs) and photovoltaic cells, are being increasingly employed for display applications and for lighting applications. In the last decade, tremendous progress has been made in the area of OLEDs, and with the imaging appliance revolution underway, the need for more advanced devices that provide advanced display and/or lighting features is increasing. In addition, the development of new lightweight, low power, wide viewing angled devices have fueled an emerging interest in transiting these technologies to lighting applications while circumventing high production and commercial expenses.

The challenges associated with developing lightweight, low power, and wide viewing angled lighting applications are considerable. Different lighting applications may have different requirements in total brightness and/or lighting area. For example, display devices typically operate at surface brightness levels between approximately 3 to 100 times lower than conventional lighting sources. Further, the total emissive area of a display device, which may be defined as the product of the total package area times the fraction of the area that is emissive, may be larger than the total emissive area in most display applications. In addition, typical display applications may include extensive drive electronics which control and address individual pixels. In typical lighting applications, such individual addressable functionality may be unnecessary and may add cost to the fabrication process. Because of the differences in brightness and pixel addressability between display devices and typical devices for lighting applications, a defective OLED in each of the types of devices may have different effects. There is thus a general need to develop specific strategies to reduce and alleviate the defects that might cause an OLED based large area lighting device to fail.

As will be appreciated by one skilled in the art, the OLED includes a stack of thin organic layers sandwiched between two charged electrodes (anode and cathode). The organic layers include a hole injection layer, a hole transport layer, an emissive layer, and an electron transport layer. Upon application of an appropriate voltage to the OLED lighting device, where the voltage is typically between 2 and 10 volts, the injected positive and negative charges recombine in the emissive layer to produce light. Further, the structure of the organic layers and the choice of anode and cathode are designed to maximize the recombination process in the emissive layer, thus maximizing the light output from the OLED device. This structure eliminates the need for bulky and environmentally undesirable mercury lamps and yields a thinner, more versatile light source. In addition, OLEDs advantageously consume relatively little power. This combination of features enable OLED light sources to be deployed in more engaging ways while adding less weight and occupying less space. Further, this combination of features may also provide lighter large area lighting sources and applications.

However, the development of large area OLEDs is difficult due to failures of the OLED devices due to the presence of local defects that cause electrical shorts. Further complicating the manufacturing of OLED devices is the relatively thin width of the OLED device film. Typically, particle contamination during fabrication, asperities from electrode roughness and non-uniformities (e.g., spots or holes) in organic layer thickness may cause shorting between the anode and cathode of the OLED.

Some techniques have been developed to increase robustness to manufacturing defects, such that the overall efficiency of the OLED device may not be significantly impacted. For example, OLED elements may be arranged in parallel such that faulty or inefficient elements may be turned off. However, such a design may add complexity to the lighting application, and further, the fill factor may be reduced. The device may also still have visible defects due to shorting of a single element in the device. It may therefore be desirable to develop a device architecture that advantageously isolates faulty elements while not significantly increasing design complexity or decreasing fill factor.

### BRIEF DESCRIPTION

The present invention provides an organic device package. The organic device package includes a plurality of elements, and each of the plurality of elements includes a patterned electrode having a plurality of electrode strips electrically coupled in parallel. Each of the plurality of electrode strips has a resistance higher than the resistance of the plurality of electrode strips electrically coupled in parallel.

Another embodiment provides a method of forming an optoelectronic device. The method includes providing a first electrode layer and patterning the electrode layer to form a plurality of electrode strips, such that the electrode strips are connected in parallel. The method further includes forming an electroluminescent layer over the patterned first electrode layer and forming a second electrode layer over the electroluminescent layer.

Another embodiment provides an optoelectronic element, which includes a patterned electrode having a plurality of electrode strips connected in parallel, electroluminescent materials disposed over the patterned electrode, and a second electrode disposed over the electroluminescent materials.

In yet another embodiment, an organic device package includes a first row of elements connected in series and a second row of elements connected in series. The first row includes a first element having a first cathode, a first anode, and organic materials disposed between the first cathode and the first anode, and multiple sub-elements connected in parallel within the first element. The first row also includes a second element having a second anode, a second cathode, and organic materials disposed between the second cathode and the second anode, and multiple sub-elements connected in parallel within the second element. The first cathode of the first element is connected in series with the second anode of the second element. Further, the organic device package also includes a second row of elements. The second row includes at least two elements connected in series, and the second row is connected in parallel with the first row.

### DRAWINGS

These and other features, aspects, and advantages of the present invention will become better understood when the following detailed description is read with reference to the accompanying drawings in which like characters represent like parts throughout the drawings, wherein:

FIG. 1 illustrates an electrode pattern for a portion of an organic device, according to an embodiment of the present invention;

FIG. 2 illustrates an enlarged view of an element from the organic device electrode pattern illustrated in FIG. 1, according to an embodiment of the present invention;

FIG. 3 illustrates an enlarged view of multiple parallel electrode strips from the element illustrated in FIG. 2, according to an embodiment of the present invention;

FIG. 4 is a conceptual representation of an organic device, according to an embodiment of the present invention;

FIG. 5 is a table providing data for resistances, voltage drops, and fractional current values in the event of an element shorting in an organic device having elements with multiple parallel elements, according to an embodiment of the present invention;

FIG. 6 is a flow chart illustrating a process of fabricating an organic device having parallel elements, according to an embodiment of the present invention;

FIG. 7 illustrates an electrode pattern utilized in forming a contact for the electrode pattern illustrated in FIG. 1, according to an embodiment of the present invention;

FIG. 8 is a cross-sectional side view of an embodiment of an organic device, according to an embodiment of the present invention;

FIG. 9 illustrates a portion of an organic device having parallel connected elements, according to an embodiment of the present invention;

FIG. 10 illustrates an emissive area of a portion of an organic device having parallel elements formed from the flow chart illustrated in FIG. 6, according to an embodiment of the present invention; and

FIG. 11 illustrates the emissive area of the organic device illustrated in FIG. 10, having failed elements according to an embodiment of the present invention.

### DETAILED DESCRIPTION

Organic materials are becoming increasingly utilized in circuit and lighting area technology and have been attracting much attention due to the low cost and high performance offered by organic electronic devices and optoelectronic devices. For example, organic electronic device lighting areas have been attracting much attention in recent years for their superior performance and attributes in the areas of thinness, power consumption, and lightness. However, the development of large area OLED light sources is difficult due to fabrication techniques, which may result in local defects that cause electrical shorts and thus, failures of the OLED devices during operation. Typically, particle contamination during fabrication, asperities from electrode roughness and non-uniformities in organic layer thickness may cause shorting between the anode and cathode of the OLED. While some techniques directed towards series and parallel groupings of OLED devices may increase robustness to manufacturing defects, element shorting in such configurations may still lead to visible defects when the device is in operation. It may therefore be desirable to develop an architecture that advantageously provides fault tolerance against electrical shorts while substantially maintaining fill factor for the OLED light source. One or more embodiments discussed herein address some or all of these issues.

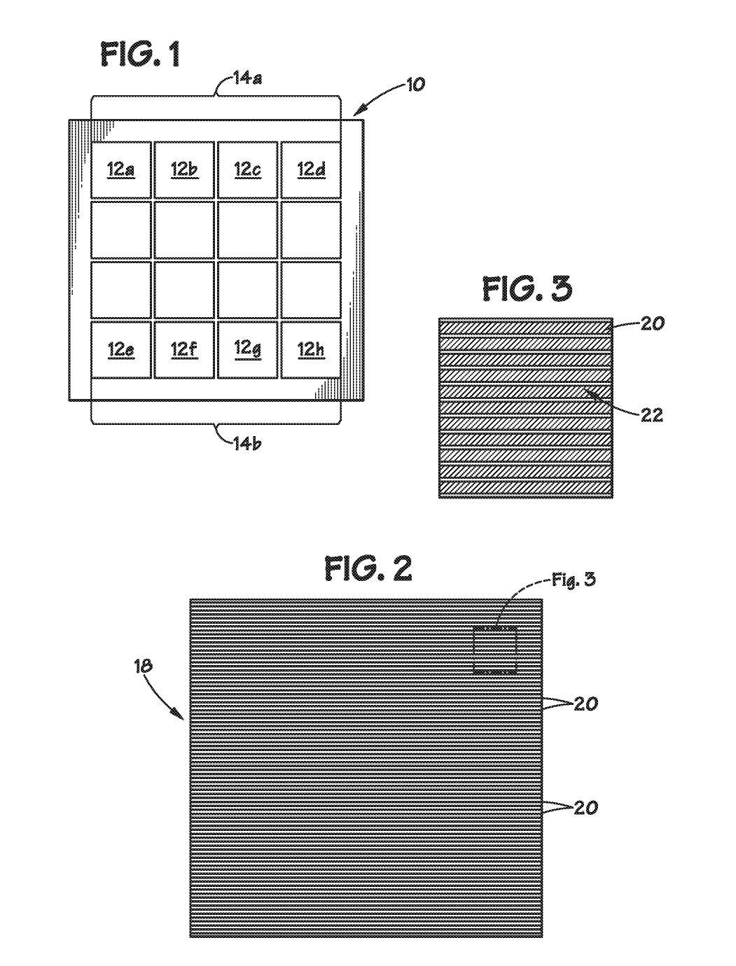

Referring to FIG. 1, an organic element package 10 from an embodiment of an organic device is illustrated. The organic device package 10 is illustrated as having a plurality of organic electronic elements 12 arranged in an array, such as the 4×4 array illustrated. However, as will be appreciated by one skilled in the art, in alternate embodiments of the present invention, a lesser or greater number of organic electronic elements or different array configurations may be envisaged. An organic device may also have one or more packages 10 of elements 12. The elements 12 may be any light emissive area, which may not necessarily be individually addressable. Further, in some embodiments, a package 10 may include a bus bar to even a voltage of one or more elements 12 in the package 10.

In one embodiment, a package 10 of an organic device may include one or more rows 14 of organic electronic elements 12 connected in series. For example, row 14a may include organic electronic elements 12a-d connected in series. In a similar fashion, the row 14b may include organic electronic elements 12e-h connected in series. In embodiments, the rows 14 may be connected in series by, for example, direct connections between the conductive electrodes of the elements 12 (e.g., a cathode of one element to an anode of another element, as will be later discussed) or a bus. The term “row” 14 is used to describe the grouping of elements 12 to better explain an embodiment according to the illustration of FIG. 1. However, in some embodiments, the grouping of elements 12 may not necessarily be linear in an array, or may not necessarily be in a row in a package. As used herein, a row of elements may refer to any grouping of elements 12 electrically coupled in series.

Further, in some embodiments, rows 14 of series-connected elements 12 may be electrically connected with each other in a parallel configuration. For example, row 14a of series-connected elements 12a-d may be connected in parallel with row 14b of series-connected elements 12e-h. However, as will be appreciated by one skilled in the art, in alternate embodiments of the present invention, a greater number of rows 14 having any number of organic electronic elements 12 may be envisioned, and any number of rows 14 may be connected in parallel in the organic device.

A parallel configuration of rows 14 of elements 12 may increase robustness to manufacturing defects, such as holes which may develop electrical short circuits, as only one row 14 of series-connected elements 12 may be isolated and deactivated when an element in the row shorts. Therefore, the other rows 14 connected in parallel may still function. While such a configuration may not significantly impact the overall efficiency of the device, the appearance of the lighting area provided by the device may be affected. For example, deactivation of an entire row 14 due to the shorting of one element 12 may be visually noticeable. Furthermore, devices may still form hot spots due to shorts in the element as the devices age. Even if elements 12 were configured to be highly parallel, such that a minimal number of elements may be deactivated when they are faulty, such a configuration may add cost or complexity to the organic device, and may also reduce the fill factor of the light source, as complexity in connecting the emissive elements may decrease the ratio of the emissive area to the total physical area of the organic device.

Embodiments of the invention relate to further dividing each element 12 into multiple sub-elements arranged in parallel. In one or more embodiments, an electrode of each element 12 in the package 10 may be patterned into thin strips which are oriented parallel to the direction of current flow. An enlargement of a patterned electrode 18 of an element 12 having multiple thin strips connected in parallel is illustrated in FIG. 2. Each sub-element in an element 12 may include an electrode strip 20. The electrode strip 20, also referred to as a sub-element electrode, may include a strip of the patterned electrode 18 in an element 12. Each of the electrode strips 20 may be connected in parallel to other electrode strips 20 in the patterned electrode 18. As each of the electrode strips 20 may be an electrode portion for a respective sub-element in the element 12, the sub-elements in the element 12 may be connected in parallel via the parallel connection of the electrode strips 20 of the patterned electrode 18.

An enlargement of a portion of the patterned electrode 18 of an element 12 which illustrates the multiple thin strips of the patterned electrode 18, or the electrode strips 20 of the sub-elements 22, is presented in FIG. 3. Each sub-element 22 may include an electrode strip 20, organic materials disposed over the electrode strip 20, and a portion of a second electrode disposed over the organic materials. While the sub-element 22 referenced in FIG. 3 does not illustrate the organic materials or the second electrode, the referenced sub-element 22 in FIG. 3 represents a position of the sub-element 22, which may be defined by the position of the electrode strip 20. In one embodiment, each element 12 consists of multiple sub-elements 22, each having electrode strips 20 connected in parallel, and in some embodiments, each element 12 may include preferably at least 10 sub-elements 22 connected in parallel.

Each of the electrode strips 20 in the element 12 may have a resistance, and in some embodiments, the resistance may be relatively high. However, due to the parallel connection of many high resistance electrode strips 20 in an element 12, the overall resistance of the element 12 may be small enough such that the overall device (i.e., the organic device which may power multiple elements 12) may still operate at a relatively low voltage. Thus, in some embodiments, the relatively high resistance of each of the parallel thin strips may be utilized advantageously. During an operation of the organic device having patterned elements 12, a small fraction of current may flow through each of the parallel sub-elements 22, such that the voltage drop for the element 12 may be relatively small. However, since there are many parallel high resistance sub-elements 22 in each element 12, the overall current load of the element 12 may be relatively high, such that the organic device may exhibit an operating brightness and total light output suitable for lighting applications.

Furthermore, in accordance with one or more embodiments, the occurrence of shorts in the organic device may also be addressed by the parallel-patterned element 12 design. For example, if one sub-element 22 were to have a short, the remainder of the transmission line through the shorted sub-element may exhibit a higher resistance relative to the array of the parallel transmission lines remaining in the element 12. Thus, a drive current applied to the element 12 may be substantially limited in a shorted sub-element, and may instead substantially flow through remaining sub-elements 22 in the element 12. Therefore, the high resistance of the electrode strip in each sub-element 22 may have the effect of limiting the amount of current which may flow through a shorted line, and in effect isolating the element in which a short is present.

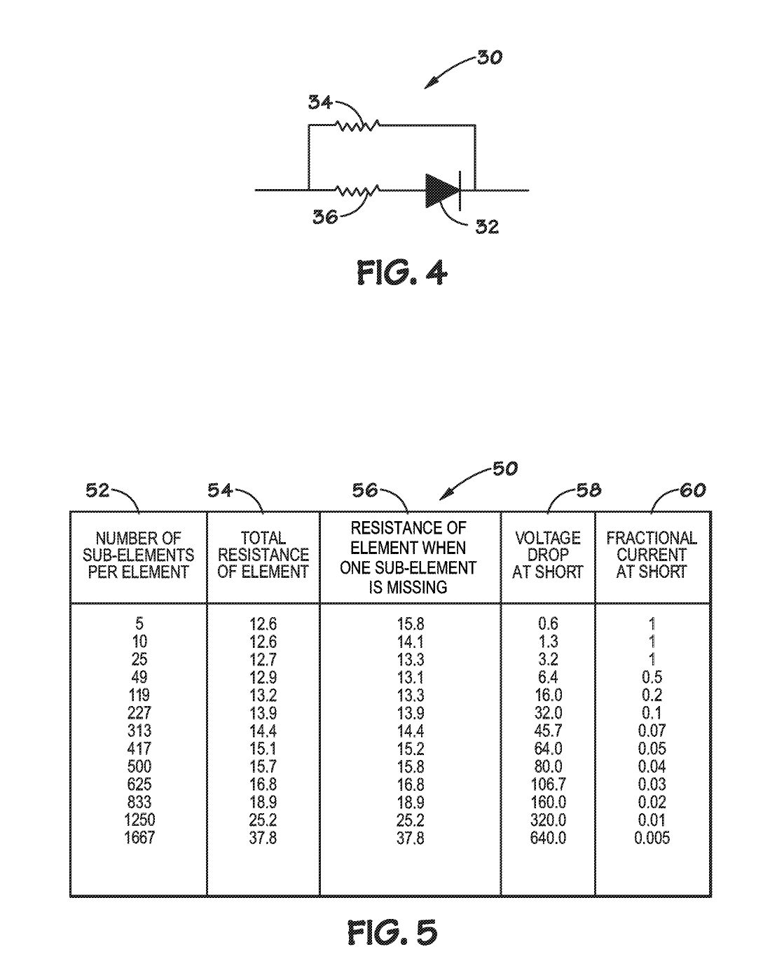

The advantages of the present invention may be further illustrated through the use of conceptual model of an organic device, as illustrated in the organic device representation 30 of FIG. 4. The organic device representation 30 may include a diode 32, a resistor 34 in parallel to the diode 32, and a resistor 36 in series with the diode 32. The diode 32 may represent the idealized behavior of a typical OLED.

For the purpose of numerical modeling, the diode 32 can be considered an ideal diode characterized by a turn on voltage Vₒₙ, which may mean that the current is very low below Vₒₙ and very high above Vₒₙ. The resistor 36 in series represents the parasitic resistance that arises from the finite conductivity of the electrode materials (i.e., the cathode and anode materials) and electrical contacts to the device. The resister 34 that is parallel to the diode 32 represents potential shorting paths between the electrodes of the organic device. The value of the resistor 34 may ideally be infinite, but in the presence of a shorting path, the resistance of the resistor 34 may fall to very small values. Thus, as explained by Ohm's law, without sufficiently high current through the resistor 34, the voltage drop across the parallel resistor 34 may be below Vₒₙ, and the diode may not be activated. Each sub-element of the OLED light source may be modeled similarly.

The representation of a sub-element as an ideal diode 32 connected to a resistor 36 in series and with parallel resistor 34 may be extended to large collection of sub-elements arranged in parallel to better explain the effects of connecting one or more sub-elements in parallel. The table 50 of FIG. 5 presents data corresponding to an element 12 (as in FIG. 1) having a patterned electrode, creating multiple sub-elements 22 connected in parallel. The data of table 50 includes resistances, voltage drops, and fractional current values in the event of a sub-element shorting in an element of an organic device. In this example calculation, the width of the illuminated area is approximately 6.35 cm, and the length of the area between the positive and negative potential connections is approximately 1.6 cm, such that the resistance of a single sub-element 22 is approximately 50 Ω(1.6 cm/6.35 cm)=12.6 Ω. Further, in this example, the 6.35 cm wide illuminated area is divided into multiple strips by pattering the ITO into strips. Each strip may be separated by a 25 micron distance to form an electrically insulating gap. As the number of strips is increased, the contribution of the sheet resistance of ITO to the resistance of each strip, Rₑ, is increased. The short is assumed to occur in all cases in the middle of the strip and to have no resistance, so that the resistance of the shorted strip is approximately half that of the calculated contribution of the ITO to resistance of the strip (i.e. equal to Rₑ/2).

Row 52 of the table 50 provides the number of sub-elements 22 in an element 12 to compare the effects of a shorted sub-element in the element 12 amongst elements 12 having different numbers of parallel-connected sub-elements 22. As used herein, a “shorted sub-element” refers to a fault in a sub-element 22 which may be caused by a hole or a spot in the electrode strip 20 of the structure 22. Row 54 provides the total resistance corresponding to each element in row 52. The total resistance 54 of an element 12 having a number of sub-elements 22 connected in parallel is calculated as the resistance Rₑ of a single sub-element 22 divided by the number of sub-elements 22 in the element 12. The resistance Rₑ was calculated by multiplying the sheet resistance of the electrode material (which may include a conductive oxide) by Lₑ/Wₑ of the electrode strip 20. The sheet resistance is assumed to be 50 Ω/square for the element area. The resistance of the remainder of the element 12 after one sub-element is missing, represented by Rₑ/(N−1), is provided in row 56.

The operating voltage for this example is 3.2 V, and the drive current I_{drive} is 20.32 mA. The voltage drop across the shorted sub-element is calculated as V_{drop}=RₑI_{drive}, which is provided in row 58. As the operating voltage is 3.2 V, a shorted sub-element having a voltage drop greater than 3.2 V may have too high a resistance to allow the drive current to pass. The fractional current f flowing through the shorted sub-element is calculated as the lesser of two quantities, f=2Vₒₚ/(RₑI_{drivel ) or f=}1, which is provided in row 60.

The data from table 50 show that elements having relatively small numbers of thin parallel connected sub-elements may provide less benefit than elements having relatively greater numbers of thin parallel connected sub-elements. For example, an element having 5 parallel connected sub-elements may have a relatively small voltage drop of 0.6, meaning the resistance in the shorted sub-element may be low enough for current to flow through, as the voltage drop across the short is smaller than the operating voltage for this example. The fractional current at the short may be 1, meaning that all the current is flowing through the short, rather than flowing through and activating the remaining sub-elements (the non-shorted sub-elements) in the element. In this example, for elements having approximately 25 sub-elements or fewer, the resistance of the shorted sub-element may be less than the total resistance of the element with one sub-element missing, such that the voltage drop across the short may be approximately at or less than the operating voltage, which may mean that the fractional current at the short is approximately 1. Thus, in some embodiments, the ratio of the resistance of an element to the resistance of a single sub-element may be approximately 5:1 or greater. In one or more embodiments, this ratio may be higher, such as 10:1, or 25:1.

In the illustrated example, an element having greater than approximately 25 parallel connected sub-elements, for example, the next data point of 49 elements, may have a voltage drop higher than the operating voltage, which may mean that not all of the drive current is going through the short. The data reflects that the fractional current at the short in this example is approximately 0.5. Further benefits may be appreciated in elements having even greater number of sub-elements per element. For example, in an element having approximately 227 sub-elements connected in parallel, the fractional current at the short may be 0.1, meaning that approximately 10% or less of the drive current is going through the short, which may correspond to a diminution in the overall current through the activated (and illuminating) sub-elements by only 10% or less.

Thus, an element 12 (as in FIG. 1) having greater than some number of sub-elements 22 connected in parallel may still function even if a defect exists on the area of the element 12. The defect may cause a short in an electrode of one or more sub-elements 22 in the element, but in some embodiments, a substantial portion of the drive current may flow to the remaining, non-shorted sub-elements 22 of the element 12, such that the element 12 may still substantially illuminate, decreasing the perceivability of shorts in the organic device.

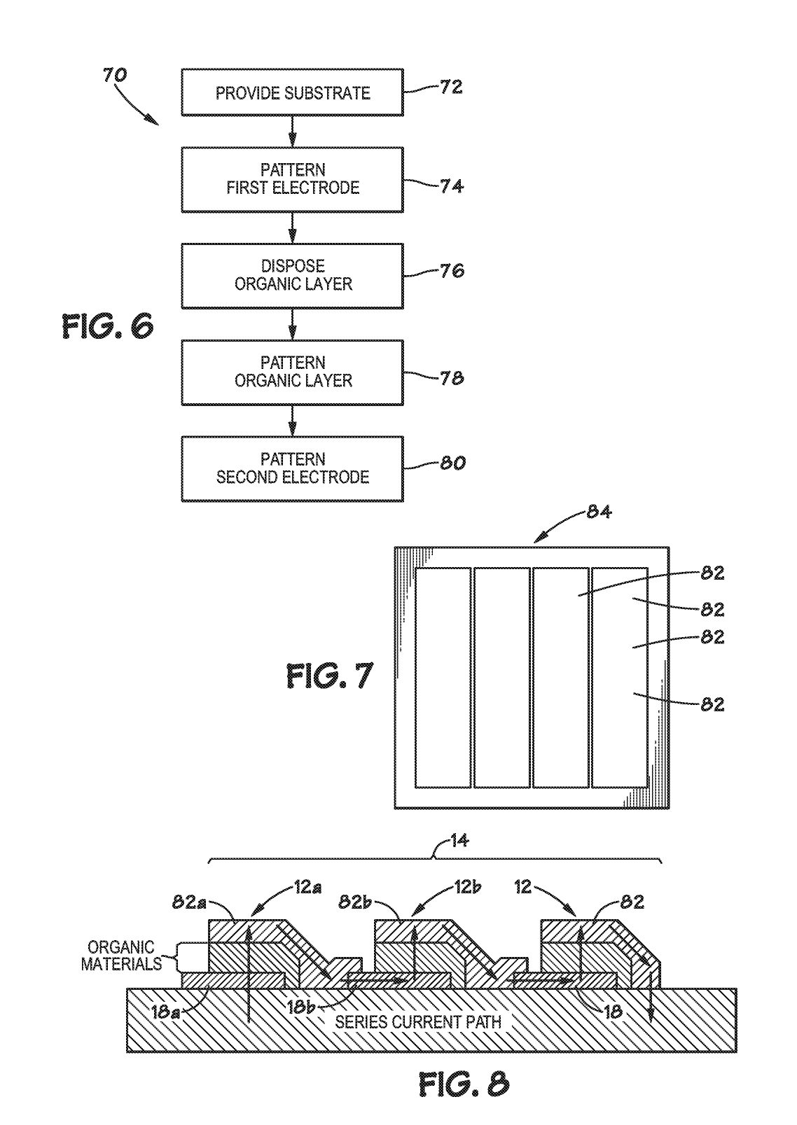

Turning now to FIG. 6, a flow chart depicting a method 70 for fabricating a portion of an organic device, in accordance with aspects of the present invention, is illustrated. In one embodiment, the organic device may include the organic element package 10 (see FIG. 1), which may include a plurality of electrically coupled organic electronic elements 12. Referring again to the configuration of the organic element package 10 from FIG. 1 as an example, the elements 12 may be connected in series to form rows 14, and each row 14 may be connected in parallel with one or more other rows 14. Furthermore, in accordance with the present invention, each element 12 may include multiple sub-elements 22 connected in parallel. Various methods may be utilized to form the sub-elements 22. For example, an electrode may be patterned through standard photolithographic techniques, or through selective application of an etchant material through printing techniques such as screen or stencil printing. Further, laser ablation of the electrode may also result in the selective patterning of the electrode to form the thin strip configuration of the electrode strips 20 for the sub-elements 22 in the elements 12. One example of a process for forming an element 12 having multiple sub-elements 22 connected in parallel is presented in the method 70 of FIG. 6.

The method 70 summarized in FIG. 6 begins at step 72. In step 72, a substrate is provided. In one embodiment, the substrate may include a flexible substrate, such as, but not limited to, plastic, a metal foil, or flexible glass. Alternatively, the substrate may include non-flexible substrates, such as, but not limited to, plastic, glass, silicon, a metal foil or combinations thereof. Further, the substrate may be substantially transparent or opaque, depending on the intended direction of light emission. Accordingly, for bottom-emitting organic electronic elements, the substrate may be substantially transparent. As used herein, “substantially transparent” refers to a material allowing a total transmission of at least about 50%, preferably at least about 80%, of visible light. Alternatively, for top-emitting organic electronic elements, light may be transmitted from the organic electronic element through the cathodes. Consequently, the substrate may be opaque.

At step 74, a plurality of first electrodes may be patterned on the substrate. It may be noted that the electrodes that are patterned first may be referred to as first electrodes since they may be first patterned in this particular method 70 of forming a portion of an organic device. In embodiments, the first electrodes may be either a cathode or an anode of the organic element (or sub-elements). Further, in embodiments, the first electrodes may not necessarily be patterned first. The plurality of first electrodes may include a first material that is transparent to the light emitted by the organic device package. For example, the first material may include a conductive oxide such as indium tin oxide (ITO), or tin oxide. In addition, a thickness of the first electrodes may be in a range from about 10 nm to about 100 μm. For example, a typical thickness may be approximately 100 nm. In certain embodiments, the plurality of first electrodes may include a first material that is transparent to the light absorbed by the organic device package. Furthermore, in certain other embodiments, the plurality of first electrodes may include a first material that is transparent to the light modulated by the organic device package.

The substrate with the conductive oxide coating may be cleaned, and may also be coated with a positive photoresist, such as AZ1512 to approximately 1.5 (micrometers) to 2 (micrometers) thick, and then baked. In one embodiment, the substrate with the conductive oxide and photoresist coatings may be baked for 10 minutes at 110 degrees Celsius. The substrate may then be exposed to a light (e.g., ultraviolet light) through a photomask patterned with metal in the desired line pattern for forming the thin of the conductive oxide, which may form the electrode strips 20 of FIG. 3. The photomask may be in direct contact with the photoresist coat of the substrate. The photoresist coating may then be developed using OCG-809 2:1 and submerged into an etch bath (e.g., an ITO etch bath having hydrochloric acid (38%): nitric acid (70%): DI water (10:1:10)). For example, the photoresist coating may be submerged in for some duration and at some temperature, such as for 4 minutes at 45 degrees Celcius, in one embodiment. Any residual acid may then be removed from the substrate, and the photoresist may be removed (e.g., using acetone and/or photoresist strippers ST22 and PRS1000). The patterned substrates may be cleaned and cut to form elements. The organic device elements may be of different sizes, and may depend on the dimensions or the configuration of the organic device. In one embodiment, elements may be made by forming a 6 inch by 6 inch square glass substrate in the process 70, and cutting 6 in×6 in square into smaller 1 in×1 in square elements.

Furthermore, the electrode strips 20 may be approximately 0.002 in wide and separated by 0.002 in. in the substrate. Thus, in this example, there may be approximately 125 parallel sub-elements 22, as there are approximately 125 parallel electrode strips 20. In some embodiments, the electrode strips 20 may be wider than the space between each electrode strip 20, which may increase the area of the sub-elements 22 and the electroluminescent area of each element 12, thus possibly increasing the fill factor of the organic device.

Subsequently, at step 76, one or more organic layers may be disposed on the plurality of first electrodes. The organic layers may be any electrically active organic material or electroluminescent material, and may be disposed by employing techniques, such as, but not limited to, spin-coating, ink-jet printing, direct and indirect gravure coating, screen-printing, spraying, or physical vapor deposition. The organic layers may serve as an intermediate layer between the respective electrodes of each of the plurality of organic electronic elements. Typically, the overall thickness of the organic layers may be in a range from about 1 nm to about 1 mm, preferably in a range from about 1 nm to about 10 μm, more preferably in a range from about 30 nm to about 1 μm and even more preferably in a range from about 30 nm to about 200 nm.

In some embodiments, the deposited organic layers (from step 76) may be patterned, at step 78. In one embodiment, the organic layers may be patterned such that they are coincident with the underlying patterned electrodes. Alternatively, the organic layers may form a continuous layer over the patterned electrodes. Further, the organic layer may be patterned to form a plurality of openings therethrough. As will be appreciated, the openings are generally formed by creating holes in the organic layers. That is, the plurality of openings may be configured to facilitate electrical coupling between the bottom and top electrodes of the organic device package. In some embodiments, the opening may facilitate electrical coupling between the anode of one element or one element to the cathode of a different element or a different element.

The plurality of openings may be formed by selective removal of the organic layer employing techniques such as laser ablation. As will be appreciated, ablation is defined as the removal of material due to incident light. The openings in the organic layer may be patterned by the selective removal of the organic layer by photochemical changes that may include a chemical dissolution of the organic layer, akin to photolithography. Typically, the organic layer may be cleared by a pressurized inert gas, such as nitrogen or argon, prior to ablating the organic layer. Alternatively, techniques such as ink-jet printing may be utilized to form the plurality of openings.

Subsequently, at step 78, a plurality of second electrodes may be patterned on the organic layer. The plurality of second electrodes may simply refer to a second electrode material that forms the organic device in the method 70. In embodiments, the second electrode may be either a cathode or an anode, and may not necessarily be the second formed electrode. The second electrode may be patterned over the element 12. In some embodiments, the second electrode may not necessarily be patterned over each individual sub-element 22 in the element, but over the entire element 12. For example, FIG. 7 illustrates an example of a second electrode pattern 84 which may form a top contact for the first electrode pattern of the organic device package 10 (depicted in FIGS. 1-3). The second electrode pattern 84 may include a plurality of second electrodes 82 for each element 12, and the second electrodes 82 may be continuous over one or more contiguous elements 12 in the package 10 (FIG. 1).

The plurality of second electrodes 82 may include a second material that is transparent to light emitted by the organic device package, such as ITO. Alternatively, the plurality of second electrodes may comprise a reflective material, such as a metal, where the metal may include aluminum (Al) or silver (Ag). Also, the thickness of the top electrode may be in a range from about 10 nm to about 100 μm, preferably in a range from about 10 nm to about 1 μm, more preferably in a range from about 10 nm to about 200 nm and even more preferably in a range from about 50 nm to about 200 nm. In certain embodiments, the plurality of second electrodes 82 may include a second material that is transparent to the light absorbed by the organic device package. Furthermore, in certain other embodiments, the plurality of second electrodes may include a second material that is transparent to the light modulated by the organic device package.

Additionally, at step 80, the plurality of second electrodes 82 may be patterned to facilitate series coupling between a plurality of organic electronic elements 12. The cross-sectional side view of a plurality of organic elements 12 is provided in FIG. 8 to depict a side view of series coupling. In accordance with one embodiment of the present invention, the organic device package may include a row 14 of at least a first organic electronic element 12a and a second organic electronic element 12b connected in series, where each of the first and second organic electronic elements 12a and 12b includes respective first electrode 18 and a second electrode 82. As discussed, the first electrodes 18 of the first and second elements may be patterned into thin strips, forming electrode strips 20 which are connected in parallel within each of the elements 12. These electrode strips 20, which are not illustrated in FIG. 8, may be configured lengthwise into the page.

In a presently contemplated configuration, series electrical coupling between the first and second organic electronic elements 12a and 12b may be achieved between the second electrode 82a of the first organic electronic element 12a and the patterned first electrode 18b of the second organic electronic element 12b. In other words, the second electrode 82a of the first organic electronic element 12a may be patterned to electrically couple in series the first and second organic electronic elements 12a and 12b by sizing the second electrode 82a to span a portion of the patterned first electrode 18b of the second organic electronic element 12b. Consequently, the first and second organic electronic elements 12a and 12b may be electrically coupled in series to form a portion of the row 14.

Subsequently, one or more substrates may be coupled in an organic device by applying pressure to the organic device package. Alternatively, the coupling between the first and second substrates may be formed via heating the organic device package. Further, a combination of application of pressure and heat may be employed to couple the first and second substrates to form the organic device package. Additionally, the organic device package may be cured via heating the organic device package. Alternatively, the organic device package may be cured by exposing the organic device package to ultra-violet radiation.

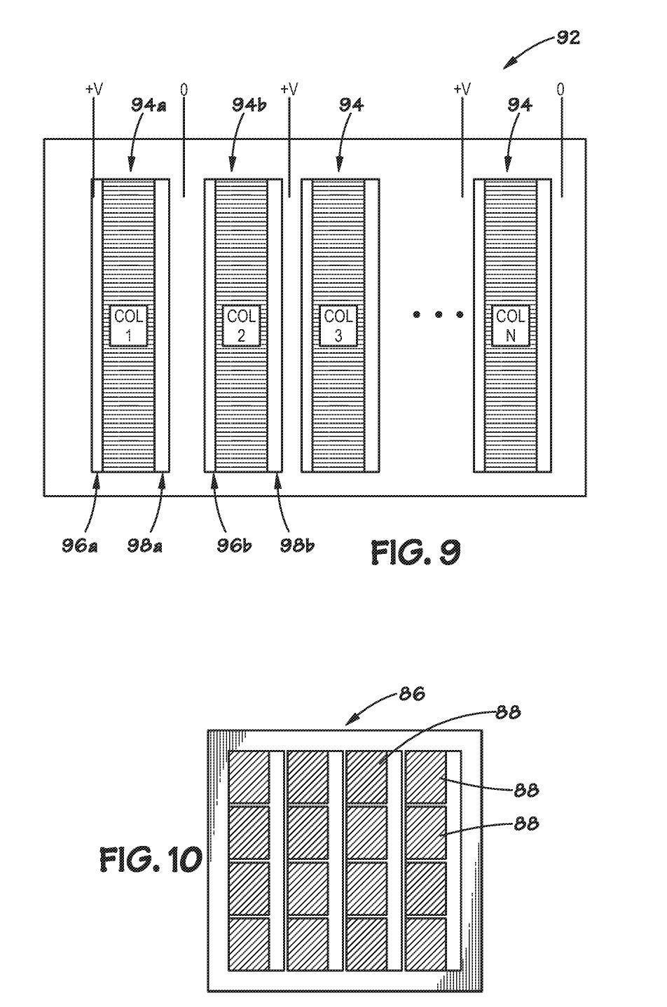

In one or more embodiments, parallel electrical coupling may also be achieved between the organic elements 12. FIG. 9 illustrates an example of a portion of an electronic device 92 connected in parallel. The parallel connected device 92 may include columns 94 of organic elements. Each column 94 may include one element 12 (as in FIG. 1), or multiple rows of elements 12. Each column 94 may also be coupled to a first electrode bus line 96 and a second electrode bus line 98. In some embodiments, the first electrode bus line 96 may be electrically coupled to the first electrode (e.g., the anode, in an embodiment) of the element(s) 12 in each column 94, and the second electrode bus line 98 may be electrically coupled to the second electrode (e.g., the cathode, in an embodiment) of element(s) 12 in each column 94. Further, the second electrode bus line 98a of one column 94a may be connected to the first electrode bus line 96b of an adjacent column 94b. A common voltage may be applied to the connected bus lines (e.g., 98a and 96b) between adjacent columns 94 (e.g., 94a and 94b). In some embodiments, a parallel configuration of elements 12, in addition to the parallel configuration of sub-elements 22 in each element 12, may further improve the performance of the organic device.

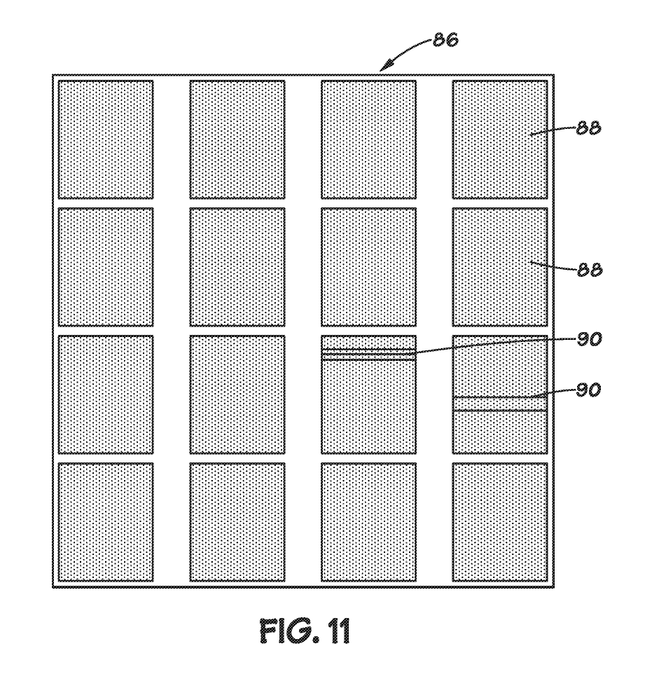

An example of an emissive area of a portion of an electronic device having elements 12 with a bottom electrode patterned into multiple thin electrode strips, forming multiple sub-elements 22 connected in parallel, is illustrated in FIG. 10. The emissive area 86 may represent the emissive portions of an organic device package 10, as illustrated in FIG. 1. Each of the emissive elements 88 may represent the emissive portions of the elements 12. Each of the elements 12 may have parallel connected sub-elements 22 which are not individually shown in FIG. 10. However, each of the sub-elements 22 in the elements 12 may be activated by a drive current to emit light for the organic device to form the emissive area 86.

In accordance with the present invention, shorts in one or more sub-elements 22 in an element 12 may not result in a failure of the entire element 12, and may not result in a readily perceivable defect in an organic device package or the entire organic device. For example, as illustrated in FIG. 11, the one or more elements may have shorted sub-elements 90. The shorted sub-elements may be deactivated, but due to the high resistance of each individual sub-element and the connection of many sub-elements in parallel, the drive current may still pass to the remaining sub-elements in the element, such that the remaining sub-elements may still be activated. Thus, the emissive element 88 may still emit substantially more light than if the entire element had been deactivated due to a shorted sub-element. Further, such sub-element shorts may not be substantially visible in the emissive area 86, or in an organic device having one or more emissive areas 86.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. An organic device package comprising a plurality of elements, wherein each of the plurality of elements comprises a patterned electrode comprising a plurality of electrode strips electrically coupled in parallel, wherein each of the plurality of electode strips comprises a resistance higher than a resistance of the plurality of electrode strips electrically coupled in parallel.

2. The device of claim 1, wherein the patterned electrode comprises an anode of each of the plurality of elements.

3. The device of claim 1, wherein the patterned electrode comprises a cathode of each of the plurality of elements.

4. The organic device package of claim 1, comprising a plurality of rows comprising the plurality of elements, wherein the plurality of elements in one of the plurality of rows are electrically coupled in series.

5. The organic device package of claim 4, wherein one or more of the plurality of rows are electrically coupled in parallel.

6. The organic device package of claim 1, wherein one or more of the plurality of elements is electrically coupled in parallel.

7. The organic device package of claim 1, wherein a ratio of the resistance of the plurality of electrode strips electrically coupled in parallel to the resistance of each of the plurality of electrode strips is approximately 5:1 or greater.

8. The organic device package of claim 1, wherein each of the plurality of electrode strips comprises a length and a width, wherein the length is longer than the width, and wherein the current flows in the direction of the length of each of the plurality of electrode strips.

9. The organic device package of claim 1, wherein each of the plurality of elements comprises a second electrode and electroluminescent materials between the patterned electrode and the second electrode.

10. The organic device package of claim 9, wherein a second electrode of a first element of the plurality of elements is electrically coupled to a patterned electrode of a second element of the plurality of elements.

11. The organic device package of claim 1, wherein the resistance of each of the plurality of electrode strips is sufficiently high such that if one of the plurality of electrode strips shorts, a current flows substantially to functioning electrode strips of the plurality of electode strips.

12. The organic device package of claim 1, wherein the plurality of electrode strips comprises a sufficient number of electrode strips such that the resistance of one of the plurality of electrode strips is higher than the resistance of the plurality of electrode strips electrically coupled in parallel.

13. The organic device package of claim 1, wherein the plurality of electrode strips comprises at least 10 electrode strips.

14. A method of forming an optoelectronic device comprising:
providing a first electrode layer;
patterning the first electrode layer to form a plurality of electrode strips, wherein the electrode strips are connected in parallel;
forming an electroluminescent layer over the patterned electrode layer; and
forming a second electrode layer over the electroluminescent layer.

15. The method of claim 14, wherein forming the second electrode layer comprises providing an electrical connection between the second electrode layer of a first optoelectronic device and the patterned first electrode layer of a second optoelectronic device.

16. The method of claim 14, wherein patterning the first electrode layer comprises forming the plurality of electrode strips such that each of the plurality of electrode strips comprises a resistance higher than a total resistance of the plurality of electrode strips.

17. The method of claim 14, wherein patterning the first electrode layer comprises using photolithographic techniques.

18. The method of claim 14, wherein patterning the first electrode layer comprises using selective application of an etchant material through printing techniques.

19. The method of claim 14, wherein patterning the first electrode layer comprises using laser ablation.

20. An optoelectronic element comprising:
a patterned electrode comprising a plurality of electrode strips connected in parallel;
electroluminescent materials disposed over the patterned electrode; and
a second electrode disposed over the electroluminescent materials.

21. The optoelectronic element of claim 20, comprising a plurality of sub-elements, wherein each of the plurality of sub-elements comprises one of the plurality of electrode strips, electroluminescent materials, and a portion of the second electrode.

22. An organic device package comprising:
a first row of elements connected in series, wherein the first row comprises:
a first element having a first cathode, a first anode, and organic materials disposed between the first cathode and the first anode, and multiple sub-elements connected in parallel within the first element; and
a second element having a second anode, a second cathode, and organic materials disposed between the second cathode and the second anode, and multiple sub-elements connected in parallel within the second element, and wherein the first cathode is connected in series to the second anode; and
a second row of elements, wherein the second row comprises a third element and a fourth element connected in series, and wherein the first row and the second row are connected in parallel.

23. The organic device package of claim 22, wherein each sub-element of the multiple sub-elements connected in parallel has a resistance that is higher than a resistance of the first element and higher than a resistance of the second element.

24. The organic device package of claim 22, wherein each of the multiple sub-elements connected in parallel is configured to substantially limit current through a shorted one of the multiple sub-elements.

25. The organic device package of claim 22, wherein each sub-element of the multiple sub-elements connected in parallel has a resistance that is approximately five times greater than a resistance of the first element and approximately five times greater than a resistance of the second element.
